(19) United States
(12) Patent Application Publication
(10) Pub. No.: US 2011/0148092 A1
(43) Pub. Date: Jun. 23, 2011

(54) Laser Imaging and Its Use In Security Applications

(76) Inventors: Anthony Jarvis, Cheshire (GB); Christopher Wyres, Cheshire (GB)

(21) Appl. No.: 13/060,615

(22) PCT Filed: Sep. 10, 2008
(86) PCT No.: PCT/GB08/50811

§ 371 Date: Feb. 24, 2011

(51) Int. Cl. B42D 15/00; B41M 3/14; B44F 1/12; G03F 7/20

(52) U.S. Cl. 283/67; 428/29; 430/292

(57) ABSTRACT

A method of forming an invisible indicium on an article that comprises an outer opaque layer and an inner, laser-imageable layer, which comprises (5) irradiating the article with a laser, whereby the laser radiation passes through the opaque layer, and causes the laser-imageable layer to change colour. The article can be scanned, as a security check.

### FIELD OF THE INVENTION

This invention relates to laser imaging and its use in security applications.

### BACKGROUND OF THE INVENTION

There is a growing demand for marking articles with covert indicia in order to prevent counterfeiting, forgeries and ID theft. This includes official documents such as passports, identity cards, banknotes, high value branded goods, pharmaceutical compositions, foodstuffs and pin numbers or other access codes.

U.S. Pat. No. 5,719,939 discloses the creation of a unique pattern of overlying individual fibers which are embedded in a transparent base material, such that the fibers form differing geometrical configurations which are optically scannable through a surface of the transparent base material. This system suffers from several drawbacks; notably, it cannot be performed on a rapidly moving production line.

WO98/40224 describes a method of marking glassy thermoplastic polymeric material with a sub-surface mark. Laser radiation is directed at the surface of the material and this produces localised stresses within the material which cannot be detected at the surface by the naked eye, but which are capable of being rendered visible under polarised light.

However, in all of these techniques the indicia are placed overtly on the article. Indicia that cannot be seen with the human eye are even more difficult to reproduce than those that are visible.

### SUMMARY OF THE INVENTION

The present invention is a method of forming an invisible indicium on an article that comprises an outer opaque layer and an inner laser-imageable layer, which comprises irradiating the article with a laser, whereby the laser radiation passes through the opaque layer and causes the laser-imageable layer to change colour.

The outer layer is generally opaque to the human eye but transparent to laser radiation. The indicium is produced in the inner laser imageable layer, but this cannot be seen through the outer human eye opaque layer.

Laser imaging/marking is particularly advantageous for this application, as it allows infinitely variable information to be applied to an article.

### BRIEF DESCRIPTION OF THE DRAWINGS

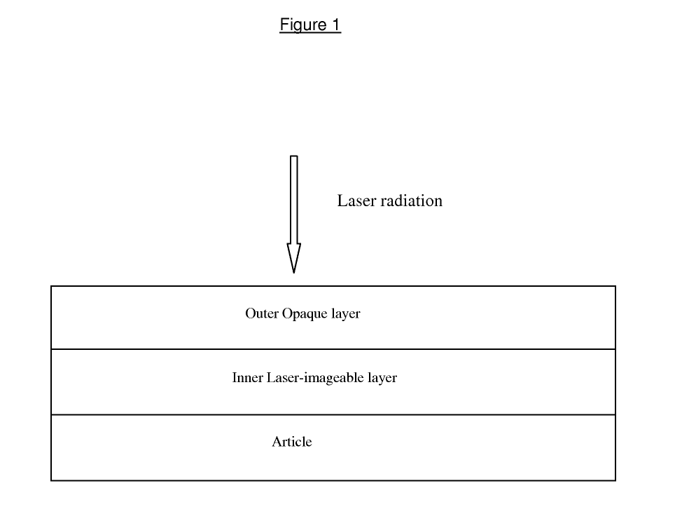

The accompanying drawing (FIG. 1) is a schematic representation of an embodiment of the invention.

### DESCRIPTION OF PREFERRED EMBODIMENTS

A laser-imageable composition utilised in this invention comprises any substance or combination of substances which change appearance or absorption profile when irradiated by a laser. The laser-imageable composition can be included within the article, such as a moulded plastic article made using a masterbatch technique, or added to paper during manufacture, or applied directly to the article such as via a spray, or applied to the article as part of a coating application using a printing technique.

Preferred examples of laser-imageable compositions that form part of the present invention are disclosed in WO02/068205, WO02/074548, WO04/043704, WO2005/012442, WO2005/068207, WO2006/018640, WO2006/051309, WO2006/129086, WO2006/129078, WO2007/045912 and WO2007/063339, the content of each of which is incorporated herein by reference. Examples can also be found in WO2006/063165, US2007032569, U.S. Pat. No. 7,169,471, U.S. Pat. No. 5,413,629, U.S. Pat. No. 5,955,224, WO2006/052843, WO2005/026247 and WO2005/047010, the content of each of which is incorporated by reference. Particularly preferred examples of constituents of the laser-imageable compositions are ammonium octamolybdate (AOM), leuco dyes, carbazoles, diacetylenes, and dehydration agents with hydroxyl-containing compounds.

When employing a near-infrared laser, it is desirable to incorporate a near-infrared absorbing substance in the formulation. Examples include near infrared absorbing compounds such as those that have an absorbance maximum similar to the wavelength of the near infrared radiation employed and preferably have little or no visible colour. Suitable examples include copper compounds such as copper (II) hydroxyl phosphate (CHP) supplied as Fabulase 322 by Budenheim, mixed metal oxide compounds particularly non-stoichiometric reduced versions such as reduced indium tin oxide (such as Degussa's AdNano products) or reduced antimony tin oxide, organic polymers such as the conductive polymer product Baytron® P supplied by HC Starck, coated inorganic particles including antimony tin oxide coated micas and the Lazerflair and Iriodin products supplied by Merck, and near infrared absorbing organic molecules, known to those skilled in the art as NIR dyes/pigments. Types of NIR dyes/pigments than can be used comprise, but are not limited to: families of metallo-porphyrins, metallo-thiolenes and polythiolenes, metallo-phthalocyanines, aza-variants of these, annellated variants of these, pyrylium salts, squaryliums, croconiums, amminiums, diimoniums, cyanines and indolenine cyanines.

Examples of organic compounds that can be used in the present invention are taught in U.S. Pat. No. 6,911,262, and are given in “Developments in the Chemistry and Technology of Organic dyes”, J Griffiths (ed), Oxford: Blackwell Scientific, 1984, and “Infrared Absorbing Dyes”, M Matsuoka (ed), New York: Plenum Press, 1990. Further examples of the NIR dyes or pigments of the present invention can be found in the Epolight™ series supplied by Epolin, Newark, N.J., USA; the ADS series supplied by American Dye Source Inc, Quebec, Canada; the SDA and SDB series supplied by HW Sands, Jupiter, Fla., USA; the Lumogen™ series supplied by BASF, Germany, particularly Lumogen™ IR765, IR788 and IR1055; and the Pro-Jet™ series of dyes supplied by FujiFilm Imaging Colorants, Blackley, Manchester, UK, particularly Pro-Jet™ 830NP, 900NP, 825LDI and 830LDI and the Filtron™ products supplied by Gentex Corp of Carbondale, Pa.

Other energy absorbing components include UV absorbers, visible dyes and pigments, and agents to absorb 10.6 microns energy such as inorganic particles such as calcium salts such as the phosphate, hydroxyphosphate and carbonate, talc, clays, micas, titanium dioxide, molybdates such as ammonium octamolybdate and the like.

A laser imageable layer may also comprise an acid or base generating agent. The acid generating agent can be a thermal or photo acid generating agent. Examples include ‘onium’ type compounds particularly sulphonium and iodonium agents such as triarylsulphonium hexafluoroantimonate salts in propylene carbonate at 50%.

Each indicium can be comprised of 2-dimensional shapes such as lines, dots, circles, elipses, polygons etc. or combinations thereof. The shapes can be geometric or non-geometric. The shapes can be monochrome, multicoloured or combinations of both. The indicium can be any indicium known to those skilled in the art. Examples include human or machine-readable code, such as symbols, barcodes or matrix codes.

The invention is particularly suitable for the generation of machine-readable codes such as barcodes, as this allows the articles to be automatically identified and tracked throughout their lifecycle down to an individual level. This then provides the basis of a ‘track and trace’ system for the articles.

A definition of a barcode and other symbologies that form part of the present invention can be found at http://en.wikipedia.org/wiki/Barcode.

A laser-imageable composition can be incorporated into a structure beneath a substrate which is opaque to visible light but transparent to NIR light. This allows a coloured indicium of the present invention to be created in the laser-imageable composition using a NIR laser that is not visible to the eye, but can be detected using a NIR scanner such as a camera.

The profile of the laser beam can be tailored to any given shape, size or energy distribution, using appropriate beam-shaping optics.

The laser can have an emission wavelength in the region 200 nm-20 μm. Preferred lasers are carbon dioxide lasers, NIR lasers, visible band lasers and UV lasers. Particularly preferred lasers are NIR lasers, such as DPSS lasers, fibre lasers, diode lasers and laser diode arrays. Both pulsed and continuous wave lasers can be used. Non-coherent and broadband radiation can also be used. In this case images can be produced using a mask.

The article can be any substrate, such as glass, film, paper, plastics, wood, foodstuffs, pharmaceuticals or any substance that a laser-sensitive agent can be incorporated into. The laser-sensitive agent can also be formulated into an ink, paint or lacquer, and then applied to the substrate using any suitable technique. Particularly preferred substrates are those that can be used to make banknotes, the outer shell of pharmaceutical tablets, excise stamps, ID and high value documents such as passports and driving licenses, the packaging of consumer goods, and those used to divulge pin numbers and access codes.

The present invention is the creation of indicia on an article, using a laser-imageable composition whereby a laser causes the composition to change colour, through a layer opaque to the human eye but transparent to laser radiation. This is illustrated schematically in the accompanying drawing (FIG. 1).

Such a system is useful in security applications where indicia such as barcodes and the like, and other information such as human-readable pin numbers and text, can be created on an article but cannot be read or seen by the human eye due to the overlying opaque layer. However, such indicia and information can be read through the overlying opaque layer using a suitable scanning device. If desired, the opaque layer may be removable; removal will reveal the indicia and information on the article to a suitable scanning device or to the human eye.

The laser-imageable layer can be any laser-imageable layer as described in the present invention. The opaque layer is preferably opaque to the human eye but transparent to laser radiation. A particularly preferred system is that based on a near-infrared (NIR) laser comprising a NIR-transparent but human eye-opaque overlayer, and a NIR-imageable inner layer on the article to be marked. A NIR-transparent but human eye-opaque overlayer can be created by coating a substrate substantially transparent to NIR radiation such as clear PET or clear BOPP with a coating of a ink opaque to the human eye but transparent to NIR radiation. A particularly preferred ink is one of the same colour as the indicia/information created on the laser-imageable inner layer and transparent to NIR radiation. Inks comprising perylene pigments are particularly preferred due to their high degree of NIR-transparency. C.I. Pigment Black 31 is a suitable example of such an ink. The human eye opaque/laser radiation transparent agent can also be formulated directly into the bulk of the layer as well as coated on to its surface. This could be done by extruding a film comprising the agent mixed into the polymer that comprises the film.

The following Examples illustrate the invention.

### Chemicals:

Paranol T-6320 (aqueous acrylic-urethane resin)—ex. Para-Chem.
Octafoam E-235 (defoamer)—ex. Octel.
Yamada ETAC (black/green leuco dye)—ex. Yamada Chemical Co. Ltd.
Benzyl p-hydroxybenzoate supplied by Acros.
Copper (II) hydroxyl phosphate (CHP)—was supplied by Budenheim as Fabulase 322.
N-ethyl carbazole—supplied by Aldrich.
Nitrocellulose DLX3-5—supplied by Nobel Enterprises nitrocellulose.
Elvacite 2028 (acrylic binder)—supplied by Lucite International.
Cyracure 6974 (a photoacid generator)—supplied by Dow Chemicals.
10,12-pentacosadiynoic acid—supplied by Aldrich.
AdNano reduced ITO powder was supplied by Degussa.
Paliogen Black S 0084, CI Pigment Black 31, was supplied by BASF.

### Substrates:

Natural top liner paper

White 50 μm PET film—supplied by HiFi.

Clear 50 μm PET film—supplied by HiFi.

### Lasers:

A 30W Videojet CO₂ laser connected to a galvanometer scanning head and controlled by an IBM-compatible PC and software.

A 10W SPI 1550 nm fibre laser connected to a galvanometer scanning head and controlled by an IBM-compatible PC and software.

A 10W SPI 1066 nm fibre laser connected to a galvanometer scanning head and controlled by an IBM-compatible PC and software.

A 3W Avia-Coherent 266 nm, diode-pumped, all-solid state, Q-switched laser connected to a galvanometer scanning head and controlled by an IBM compatible PC and software.

### Example A

### Outer Opaque Black Layer

The following ink formulation was prepared:

Nitrocellulose DLX3-5 dissolved in 3:1 ethanol/ethyl acetate (15%)=90 g

Paliogen Black S 0084=10 g

Mill using an Eiger-Torrance 50 ml bead mill for 15 minutes and coat on to clear PET film using a RK Proofer Printer fitted with a K-3 bar (to give about 8 gsm).

### Example 1

The following ink formulation was prepared:
Paranol T-6320=44 g
Octafoam E-235=1 g
AOM=55 g

The ink was prepared using a high speed Silverson mixer for 15 minutes prior to its application to the substrate.

### Example 2

The following ink formulation was prepared:
Paranol T-6320=44 g
Octafoam E-235=1 g
AOM=35 g
CHP=20 g

The ink was milled using an Eiger-Torrance bead mill (50 ml) for 15 minutes prior to its application to the substrate.

### Example 3

The following ink formulation was prepared:
Paranol T-6320=59 g
Octafoam E-235=1 g
AOM=35 g
AdNano reduced ITO powder=5 g

The ink was milled using an Eiger-Torrance bead mill (50 ml) for 15 minutes prior to its application to the substrate.

### Example 4

The following ink formulation was prepared:
Paranol T-6320=79 g
Octafoam E-235=1 g
Yamada ETAC=5 g
BHB=15 g

The ink was prepared using a high speed Silverson mixer for 15 minutes prior to its application to the substrate.

### Example 5

The following ink formulation was prepared:
Paranol T-6320=59 g
Octafoam E-235=1 g Yamada ETAC=5 g
BHB=15 g
CHP=20 g

The ink was milled using an Eiger-Torrance bead mill (50 ml) for 15 minutes prior to its application to the substrate.

### Example 6

The following ink formulation was prepared:
Nitrocellulose DLX3-5 15% in MEK=80 g
N-Ethyl carbazole=5 g
Cyracure 6974=15 g

The ink was prepared by stirring the above formulation for 2 hours prior to its application to the substrate.

### Example 7

The following ink formulation was prepared:
Elvacite 2028 15% in MEK=80 g
10,12-pentacosadiynoic acid=5 g
Cyracure 6974=15 g

The ink was prepared by stirring the above formulation for 2 hours prior to its application to the substrate.

Each formulation prepared in Examples 1 to 7 was coated on to natural top liner and white PET film using an RK Proofer Printer fitted with a K-3 bar to give a coat weight of approximately 6 to 8 gsm. The coated substrates were then covered by the opaque black layer prepared using the Paliogen Black ink. The bi-layer substrate composition was then laser imaged through the outer opaque black layer.

The following laser/substrate combinations were used:

Examples 1 and 4 were imaged with the CO₂ laser.

Examples 2 and 5 were imaged using the 1066 nm NIR fibre laser.

Example 3 was imaged using the 1550 nm fibre NIR laser.

Examples 6 and 7 were imaged using the 266 nm UV laser.

In each case a machine readable code and a human readable 4 digit pin number were imaged.

After imaging it was not possible to see the image in the inner imageable layer underneath the outer opaque black layer. However, removing the outer opaque black layer revealed the inner imaged layer.

1. A method of forming an invisible indicium on an article that comprises an outer opaque layer and an inner laser-imageable layer, wherein said method comprises irradiating the article with a laser, whereby the laser radiation passes through the opaque layer and causes the laser-imageable layer to change colour.

2. The method as claimed in claim 1, wherein the opaque layer is opaque to the human eye.

3. The method as claimed in claim 2, wherein the opaque layer is black.

4. The method as claimed in claim 2, wherein the opaque layer comprises a perylene colorant.

5. The method as claimed in claim 1, wherein a laser-imageable composition is provided within an article that comprises the inner layer, or forms the inner layer by being coated on to an article.

6. The method as claimed in claim 1, wherein the laser has an emission wavelength in the region 200 nm to 20 microns.

7. The method as claimed in claim 6, wherein the laser is a near infrared laser with an emission wavelength in the region 700 nm to 2500 nm.

8. The method as claimed in claim 7, where the near infrared laser is a fibre, diode or diode array laser.

9. The method as claimed in claim 1, wherein the indicium is selected from one or more of human readable text, devices, numbers or lines, dots, circles, polygons or ellipses.

10. The method as claimed in claim 1, which comprises forming a plurality of indicia which each comprise 2-dimensional shapes, and the indicia are distinct for distinct articles.

11. The method as claimed in claim 1 wherein the outer layer is opaque to the human eye but transparent to laser radiation with an emission wavelength in the region 700 to 2500 nm, and the inner layer is imageable by said 700 to 2500 nm laser radiation.

12. The method according to claim 1, wherein the imageable layer comprises a colour former.

13. The method according to claim 12, wherein said colour former is a metal oxyanion, a leuco dye, a diacetylene, or a charge transfer compound.

14. The method according to claim 13, wherein the metal oxyanion is a molybdate.

15. The method according to claim 1, wherein the inner layer comprises a near-infrared absorbing additive.

16. The method according to claim 15, wherein the near infrared absorbing additive is copper (II) hydroxide phosphate, a non-stoichiometric mixed metal oxide, a conductive polymer or an organic dye/pigment.

17. The method according to claim 1, wherein the imageable layer further comprises an acid generating agent.

18. An article comprising an outer opaque layer and an inner layer comprising or coated with a laser-imageable composition and in or on which images have been formed.

19. A method for checking the authenticity of an article as claimed in claim 18, which comprises scanning the article and determining the presence of the images.

20. The method according to claim 14, wherein the molybdate is ammonium octamolybdate.
